(19) United States
(12) Patent Application Publication
(10) Pub. No.: US 2013/0320972 A1
(43) Pub. Date: Dec. 5, 2013

(54) MAGNETIC FIELD SENSING DEVICE

(71) Applicants: Uwe Loreit, Wetzlar (DE); Sebastian Weber, Wetzlar (DE)

(72) Inventors: Uwe Loreit, Wetzlar (DE); Sebastian Weber, Wetzlar (DE)

(21) Appl. No.: 13/982,508

(22) PCT Filed: Feb. 3, 2011
(86) PCT No.: PCT/EP11/51585

§ 371 Date: Aug. 20, 2013

(51) Int. Cl. G01R 33/09

(52) U.S. Cl. CPC G01R 33/096
USPC 324/252

(57) ABSTRACT

The present invention relates to a magnetic field sensing device (50) comprising several functionally different layers (38, 60, 70), wherein a Wheatstone bridge layer (70) comprises at least two resistors (20) of a Wheatstone bridge (18), each resistor (20) comprises at least one magnetic field sensing element (10) in the form of a resistor subelement (22), and a flip conductor layer (38) comprising at least one flip conductor (30) for flipping the internal magnetization state of each magnetic field sensing element (10). The flip conductor (30) comprises a plurality of conductor stripes (32) being arranged on at least two different flip conductor sublayers (38-1, 38-2) of said flip conductor layer (38) and being electrically coupled with each other through vias.

The multilayer arrangement of said flip conductor (30) provides a compact design of said magnetic field sensing device (50), such that a decreased power consumption, decreased inductance and improved sensitivity of the magnetic field sensing device can be achieved.

### TECHNICAL FIELD

The present invention relates to a magnetic field sensing device for sensing a direction and magnitude of an external magnetic field.

### BACKGROUND ART

The AMR effect (Anisotropic Magneto Resistance Effect) is used in a wide array of sensors, especially for the measurement of the earth's magnetic field, as an electronic compass or for electric current measurement (by measuring the magnetic field created around the conductor), for traffic detection and for linear position sensing and angle sensing. Typically, AMR magnetic field sensing devices comprise magnetic field sensing elements utilizing the AMR effect, which is the property of a conductive material to change the value of its electrical resistance when an external magnetic field is applied. Using a Wheatstone bridge configuration enables a highly sensitive measurement of resistance variations of the AMR sensitive bridge resistors. Since more and more highly compact electronic devices, such as navigation systems, pulse watches, speedometers, mobile computers and similar electronic products, comprise a magnetic field sensor, the need for highly integrated and small magnetic field sensor chips arises.

It is well known that sensitivity of an AMR sensor chip can be increased by introducing a magnetic field flipping mechanism, wherein an internal magnetization of each AMR magnetic sensing element is periodically flipped, such that a differential measurement of a single component of a magnetic field can be performed. Therefore, typical sensor chips comprise a magnetic flip conductor for generating a magnetic flipping field, wherein the flip conductor is integrated in a single chip layer of the AMR sensor chip. Many electric devices incorporating a magnetic field sensor chip are powered by batteries or accumulators with low capacity. Thus it is desirable that said flipping mechanism should not consume too much electric power, whereby high flipping frequency rates should be achieved for enhancing the resolution and accuracy of the magnetic field measurement. Furthermore, since the size of the flip conductor of conventional designs dominates the overall dimensions of the magnetic field sensor chip it is further desirable to miniaturize the flip conductor design, which helps to decreases inductance and in consequence increases flipping rate.

From U.S. Pat. No. 5,247,278 A, a magnetic field sensing device is known, wherein a flip conductor is formed with a spiral design and covers the main part of the area of the magnetic field sensor chip. The layout of the flip conductor determines the size of the sensor chip. The flip conductor is arranged on a single layer and is separated from the Wheatstone bride layer and from the chip substrate by dielectric insulating layers. Arranging a comparatively large flip conductor on a single layer of a sensor chip results in a comparatively high electric energy consumption in the generation of a sufficiently large magnetic flipping field for flipping the internal magnetization of the magnetic field sensing elements, occupies a large part of the chip area, consumes a significant amount of electric energy and exhibits a high inductance, such that only comparatively low flipping frequencies can be attained which limit the temporal resolution of the magnetic field sensing.

A problem encountered with the magnetic field sensing devices known from the state of the art resides in the aspect that the magnetic field conductor is relatively large with respect to the AMR resistor configuration, consumes a relatively high amount of electric energy and does not allow to increase a flipping frequency, such that a higher miniaturization and better resolution of the magnetic field sensing device is limited. It is therefore desirable to provide an enhanced magnetic field sensing device, which enables higher integration, smaller chip size, lower power consumption, higher temporal resolution and sensitivity of the magnetic field sensing.

### DISCLOSURE OF THE INVENTION

The object of the present invention is achieved by a magnetic field sensing device according to claim 1.

The invention suggests a magnetic field sensing device comprising several functionally different layers, wherein a Wheatstone bridge layer comprises at least two resistors of a Wheatstone bridge. Each resistor of the Wheatstone bridge comprises at least one magnetic field sensing element as a subresistor. A flip conductor layer comprises at least one flip conductor for flipping the internal magnetization state of each magnetic field sensing element. The flip conductor comprises a plurality of conductor stripes being arranged on at least two different flip conductor sublayers of said flip conductor layer, wherein the conductor stripes of the sublayers are electrically coupled with each other through via connections, i.e. so-called vias. Thus, the magnetic field sensing device suggests a design of a sensor chip, wherein the flip conductor is arranged on at least two sublayers which can lie on top of each other or which may sandwich the Wheatstone resistors. Such a design requires nearly half the size of a conventional magnetic sensor chip area. This results from the multilayered structure of the flip conductor being arranged on at least two sublayers. The three-dimensional structure reduces chip size outside of the area, where the magnetic field sensing elements are located, thus making the overall size of the sensor chip more compact. Furthermore, due to the compact design, magnetic stray fields can be decreased and inductance can be reduced. The magnetically active conductor stripes adjacent to the magnetic field sensing elements can be designed with a U-shape, a meandering shape or a spiral shape and can exert equivalent or superior effects on the flipping mechanism as existing flip conductor structures. The basic concepts of the flipping mechanism follow conventional designs, i.e. flipping the orientation of the magneto-resistive stripes of each resistor relative to the conductor stripes of a flip conductor sublayer close to the magnetic sensing elements. As a result, the magnetic field sensing elements of the resistor arrangement can be located more closely to each other, such that magnetic field sensing elements are rendered more homogeneous and material impurities and fabrication defects affect two or more resistors equally, resulting in the following improvements:
improved linearity of the RIB relation curve, whereby θ is an angle of an external magnetic field to be measured with respect to an alignment of a magnetic field sensing element and R is the electric resistance of said element;
decreased sensitivity of temperature changes and fabrication variations;
reduced offset voltage V_{off} of the Wheatstone bridge configuration;
more compact design and smaller chip size;
decreased inductance of flip coil due to reduced magnetic stray field;
increased sensing frequency limit; and
decreased flipping voltage, flipping current I_{F}, and energy consumption.

In general, magnetically active conductor stripes which are designed for providing a magnetic flipping field or magnetic flipping impulse and conductor stripes for electrically conducting said active conductor stripes can be located in any arbitrary form on both sublayers. According to a preferred embodiment, the flip conductor can comprise a first set of magnetically active conductor stripes for providing a magnetic flipping field of an associated magnetic field sensing element. The first set of conductor stripes can be arranged on a first flip conductor sublayer facing a Wheatstone bridge layer side. Furthermore, the magnetic field sensing device can comprise at least one second set of conductor stripes for providing an electrical connection of said first set of conductor stripes, being arranged on at least one second flip conductor sublayer. In this way, both sublayers are designed for a specific technical purpose: the first layer comprises a first set of conductor stripes for generating the magnetic flipping field and the second layer comprises a second set of conductor stripes for connecting the first set of conductor stripes, such that a flipping current can generate a magnetic flipping field which flips the internal magnetization state of each magnetic sensing element. Preferably, the magnetically active first sublayer is located close to the magnetic field sensing elements of the resistors of the Wheatstone bridge, such that a small current can generate a magnetic flipping field being sufficient for flipping the internal magnetic state of the subresistors. Decreasing the distance between the first set of conductor stripes and the magnetic field sensing element reduces energy consumption of the flipping process.

In general, the flip conductor provides a magnetic field in parallel or anti-parallel to the internal magnetization of said magnetic field sensing element. For instance, the conductor stripe can be designed as a solenoid or a cylindrical coil. According to a preferred embodiment and following the aforementioned embodiment, said first set of conductor stripes is essentially oriented perpendicular with respect to a longitudinal alignment of said magnetic field sensing element, and said second set of conductor stripes is essentially oriented in parallel with respect to said longitudinal alignment of said magnetic field sensing element. A conductor stripe generates a magnetic field which is perpendicular to the current flow along the stripe. Therefore, a conductor stripe being oriented perpendicular with respect to the length direction of a magnetic field sensing element can generate a magnetic flipping field in parallel or anti-parallel to the internal state of the magnetic flip element for electrically connecting the perpendicular conductor stripes to the parallel-oriented stripes of said second sublayer contact of said first set of perpendicular conductor stripes. The electric connection between both sublayers is created by vias or bonding wires. In this way, a compact and efficient conductor coil arrangement with reduced geometric dimensions can be provided.

In general, the conductor stripes of said first flip conductor sublayer can be single stripes being oriented preferably perpendicular to an internal magnetization direction of associated magnetic field sensing elements. Alternatively, said conductor stripes can be U-shaped, spiral-shaped or meandering-shaped and can also comprise regions being parallel-oriented with respect to said internal magnetization direction. Such single, parallel-oriented conductor stripes, U-shaped, spiral-shaped or meandering-shaped conductor stripes can form fingers, such that multiple non-connected conductor stripes can engage with each other. According to the foregoing embodiment, said first set of conductor stripes can comprise an interdigital arrangement of said perpendicularly oriented conductor strips for providing a magnetic flipping field for a center part of said magnetic field sensing element and perpendicular conductor strips for providing a magnetic flipping field for end parts of said magnetic field sensing element. An interdigital arrangement, wherein conductor stripes with an opposing direction of current flow neighbouring each other, provides a compact design with reduced inductance and minimized magnetic stray field. The parallel-oriented conductor stripes of said second sublayer connect the fingers of the first set of conductor stripes.

According to a preferred embodiment, said first set of conductor stripes can be designed and arranged so that an increased magnetic flipping field can be provided at both end parts of each magnetic field sensing element with respect to a magnetic flipping field provided for a center part of said magnetic field sensing element. Flipping the magnetic field sensing elements is ensured by applying a comparatively strong magnetic flipping field to both ends of a magnetic field sensing element and a reduced magnetic flipping field to the center part of the magnetic field sensing element. An increased magnetic flipping field can be provided at both end parts by increasing current density at the end parts with respect to the center parts of a magnetic flipping current flowing through the flip conductor. For instance, arranging flip conductor stripes with reduced width at the end parts and with increased width at the center part of the magnetic field sensing elements or designing a flip conductor stripe with a conductance profile, such that a flipping current density is increased at the end parts of a magnetic field sensing element, provides a magnetic flipping field for a stable and reliable flipping of the internal magnetization state of the magnetic field sensing element.

According to a further preferred embodiment which is advantageous in combination with the foregoing embodiment, at least one conductor stripe of said first set of conductor stripes can comprise at least one current distribution element being designed to provide a current distribution, such that a homogeneous magnetic flipping field can be excited in a center part of said magnetic field sensing element, preferably a conductance profile or a non-conducting area, especially a recess, whereby preferably said conductor stripe is adapted for flipping the internal magnetization state of the center part of said magnetic field sensing elements. The current distribution element is designed for providing a homogeneous current distribution in the center part of a magnetic sensing element. Due to its highly compact design, the flip conductor comprises a plurality of rough edges. The current distribution element can be a hole, a recess or a non-conducting part of said first set of conductor stripes for providing a homogeneous distribution of the magnetic flipping current, preferably in a center part of a magnetic field sensing element. In this way, a homogeneous magnetic flipping field can be provided for the center part, and optionally the current distribution element can be designed to provide an increased magnetic field at the end parts of the magnetic field sensing element. If the conductor stripes consist of a not perfectly conducting material, the current distribution material can also comprise a conductance profile forcing a homogeneous current distribution in a center region and optionally an increased current distribution at the end parts of a magnetic field sensing element.

According to a preferred embodiment, said resistor can comprise at least two magnetic field sensing elements as subresistors, wherein each magnetic field sensing element comprises a Barberpole structure with a positive or a negative Barberpole alignment depending on its arrangement with respect to a current flow direction of the associated perpendicular conductor stripe of the flip conductor. In this way, the conductor stripes of an adjacent and magnetically active flip conductor sublayer sets a direction of magnetization of half the number of the magneto-resistive stripes (magnetic field sensing element) of each resistor in a Wheatstone bridge network in one direction and half the number in another direction, such that an improved linearity and enhanced sensitivity of the sensor device can be achieved. For instance, a resistor comprises at least two magnetic field sensing elements, a first element with a positive Barberpole arrangement and a second with a negative Barberpole arrangement in a series connection. Both elements are arranged with respect to their corresponding magnetically active flip conductor stripes, such that their internal magnetizations can be flipped opposing to each other. Thus, an Uₐ/H-relation curve of the Wheatstone bridge is linearized and accuracy and sensitivity are improved.

According to the foregoing embodiment, the subresistors of said at least two resistors of said Wheatstone bridge layer can be arranged in an interdigital manner. In detail, each resistor comprises a series connection of a plurality of magnetic field sensing elements. The magnetic field sensing elements of each resistor are arranged in a meandering form, whereby two series-connected elements form a “finger” and are arranged side by side. A gap is formed between two neighboring fingers of a first resistor, such that a finger of a second resistor can be interposed between said two fingers of the first resistor. In this way, fingers of a first and a second resistor can be arranged in an interdigital manner, resulting in a compact arrangement and in similar material properties and characteristics of both resistors. As a result, the overall size of the sensor chip can be reduced and linearity, accuracy and sensitivity can be improved.

According to a preferred embodiment, both longitudinal end parts of said magnetic field sensing element can have a tapered form, preferably an elliptic form. A tapered form, for instance a narrowed or attenuated elliptic for the end parts of a magnetic field elements, improves the electrical connection of said elements and reduces the strength of a magnetic flipping field for flipping the internal state of the element. In this way, overall energy consumption for the flipping mechanism can be reduced.

In general the Wheatstone bridge layer can be arbitrarily arranged with respect to said first and second flip conductor sublayer. According to a preferred embodiment, said bridge resistors can be arranged on a Wheatstone bridge layer beneath and favourably adjacent to said first flip conductor sublayer. The Wheatstone bridge layer can preferably also be arranged within said second flip conductor sublayer, whereby conducting stripes of said second flip conductor sublayer and magnetic field sensing elements of said Wheatstone bridge are arranged on the same layer. Alternatively the Wheatstone bridge layer can be sandwiched between said first and said second flip conductor sublayer, whereby the magnetic field sensing elements of the Wheatstone bridge are disposed between said first and second sublayer. It is also possible to arrange the Wheatstone bridge layer on top of said first flip conductor sublayer. The first flip conductor sublayer should be arranged close to the magnetic field sensing elements of the Wheatstone bridge for reliably flipping its internal magnetization. The magnetic field sensing elements of the Wheatstone bridge can favourably be located within the second sublayer, whereby the second set of conductor stripes is essentially oriented in parallel to the magnetic field sensing elements, which reduces the volume of the chip, shortens the length of the conductor stripes and reduces inductance and improves coupling of the magnetic field sensing elements with the magnetic flipping field of the magnetically active conductor stripes of the flip conductor. A magnetic field sensing element comprise an AMR material stripe, e.g. permalloy and attached thereto a barberpole structure of highly conducting material aligned in an angle of preferably 45° with respect to the alignment of the AMR material stripe. During processing of the barberpole structure vias for connecting the second set of flip conductor stripes and the first set of flip conductor stripes can be manufactured simultaneously using the same material as for the barberpole structure.

According to a preferred embodiment, the magnetic field sensing device can comprise a compensation conductor for generating a magnetic compensation field to compensate an external magnetic field, wherein said compensation conductor is disposed on at least one compensation conductor layer, preferably on top of said Wheatstone bridge layer and adjacent to and/or staggered with said flip conductor layer. A compensation conductor can also generate a magnetic field, but in contrast to a flip conductor, not in parallel but rather perpendicular to the length orientation of a magnetic field sensing element. The compensation conductor can generate a magnetic field being parallel to a component of the external magnetic field to be sensed, such that an external magnetic field can be compensated. The magnetic compensation field can eliminate or correct an external magnetic field and can be used for biasing the magnetic field sensing device. It can be advantageous to arrange the Wheatstone bridge layer between said flip conductor layer and said compensation conductor layer, such that magnetically active parts of each layer can be arranged close to the magnetic field sensing element. As a result, a magnetic flipping field as well as a magnetic compensation field can be generated with reduced electric energy. Compensation conductor layer and flip conductor layer can comprise two or more sublayers. It can be advantageous that sublayers of both conductor layers are staggered on each other, such that sublayers of both layers are alternatively arranged on each other.

In addition to the foregoing embodiment, it is advantageous to arrange multiple conductor stripes of said compensation conductor on at least two different compensation conductor sublayers of said compensation conductor layer. The conductor stripes of the different sublayers can be electrically coupled through vias with each other, such that a first set of compensation conductor stripes for providing a magnetic compensation field is arranged on said first compensation conductor sublayer, and a second set of compensation conductor stripes for providing an electrical connection of said first set of compensation conductor stripes is arranged on said second compensation conductor sublayer. Said first set of compensation conductor stripes can be arranged above and adjacent to said Wheatstone bridge layer and underneath said first compensation conductor sublayer. Preferably, the magnetically active conductor stripes of the first compensation conductor sublayer are placed close to the resistors of the Wheatstone bridge layer. Furthermore it is favourable to place the second compensation conductor sublayer remote from the Wheatstone bridge layer such that a magnetic field generated by the compensation conductor stripes of the second set of compensation conductor stripes does not adversely affect the compensation magnetic field of the Wheatstone bridge resistors. Alternatively the second set of compensation conductor sublayer can be located beneath the Wheatstone bridge layer such that the Wheatstone bridge layer is sandwiched between the first and second set of compensation conductor sublayers, whereby the magnetic field generated by the conductor stripes of the second set of compensation conductors stripes contributes to the compensation magnetic field generated by the first set of compensation conductor stripes. In a preferred embodiment a set of conductor stripes of the second flip conductor sublayer is arranged in parallel with AMR material stripes representing magnetic field sensing elements on a surface of a chip substrate. On top of this layer a set of conductor stripes of the first compensation conductor sublayer is arranged. Subsequent a set of flip conductor stripes of the first flip conductor sublayer is arranged and hereafter on top of the chip layer arrangement a set of compensation conductor stripes of the second compensation conductor sublayer is arranged. The sublayers can be contacted by vias. Thus a staggered arrangement of alternating sublayers of compensation conductor stripes and flip conductor stripes provide a compact, highly sensitive and energy efficient magnetic field sensing device. This embodiment suggests transferring the aforementioned concept of a multiple flip conductor layer arrangement to a multiple compensation conductor layer arrangement. In this way, advantages and improvements with respect to the flip conductor concept also hold for the compensation conductor.

According to a preferred embodiment, at least a part of said flip conductor and/or said compensation conductor is arranged essentially in a U-shape, a spiral shape and/or a meandering shape. All of these arrangements comprise perpendicularly and parallel-oriented elements which can be assigned to magnetically active and electrically connecting conductor stripes of the flip conductor and/or the compensation conductor. All arrangements provide magnetically active conductor stripes with opposing magnetic fields and can be implemented in a compact form. These arrangements can also be combined, i.e. a sublayer can comprise conductor stripes being U-shaped and spiral-shaped, U-shaped and meandering-shaped, or otherwise.

According to a preferred embodiment, the material of said flip conductor and/or said compensation conductor is highly conductive, preferably comprising copper, aluminum, silver, gold or an alloy thereof, and is preferably identical to the material forming the Barberpole structure. A highly conductive conductor can generate a high current even with a low voltage of a battery-driven device, such that a sufficiently large magnetic field can be produced. Using an identical material for the Barberpole structure and the conductor stripes reduces manufacturing complexity, whereby the Barberpole structure and the conductor stripes can be manufactured simultaneously.

In general, a single flip conductor is provided for simultaneously flipping all magnetic field sensing elements of the Wheatstone bridge. According to a preferred embodiment, two or more electrically separated flip conductors for independently flipping a magnetization state of at least one magnetic field sensing element of a bridge resistor can be provided. Two independent flip conductors allow the independent flipping of half of the magnetic field sensing elements. Both flip conductors can generate four different flip states of the magnetic field sensing elements of a Wheatstone bridge resistor, such that the sensitivity of the Wheatstone bridge can be switched on or off. This allows the measuring of the offset voltage of the bridge, as well as performing a self-test of the bridge. The offset voltage can be used to further improve accuracy of the magnetic field sensing device.

The embodiments listed above comprise a number of non-limiting examples. For instance concepts of the flip conductor arrangement and compensation conductor arrangement can be combined, merged with or transferred to each other. A resistor can comprise at least one or multiple series-connected magnetic field sensing elements, preferably AMR stripes. The Barberpole arrangement of the magnetic field sensing elements of each resistor can be identical or alternating, depending on the arrangement with respect to the flip conductor. The flip conductor sublayer can be stacked or can sandwich the Wheatstone bridge layer. Preferably, the Wheatstone bridge layer is arranged within the second sublayer of the flip conductor. A compensation conductor layer can be stacked on top of or underneath a flip conductor layer. Preferably, the flip conductor layer and the compensation conductor layer sandwich said Wheatstone bridge layer.

### BRIEF DESCRIPTION OF DRAWINGS

Hereinafter, the invention will be described in greater detail with reference to the attached drawings. These schematic drawings are used for illustration only and do not in any way limit the scope of the invention. In the drawings:

FIG. 1 schematically shows the AMR concept and resistance dependency with respect to an angle of an external magnetic field of a magnetic field sensing element without Barberpole structure;

FIG. 2 shows the effect of a Barberpole structure with respect to FIG. 1;

FIG. 3 shows a schematic view of a Wheatstone bridge arrangement of a magnetic field sensing device of the state of the art without flip conductor;

FIG. 4 shows different schematical views of a magnetic field sensing device with flip conductor, wherein the Wheatstone bridge resistor consists of a single magnetic field sensing element, multiple magnetic field sensing elements and multiple flip conductors;

FIG. 5 shows different magnetic field sensing devices with flip conductor arrangements of a state of the art;

FIG. 6 schematically shows a first embodiment of a magnetic field sensing device with a multilayered flip conductor;

FIG. 7 shows single sublayers of the flip conductor layer of FIG. 6;

FIG. 8 shows a second embodiment of a magnetic field sensing device with an interdigital arrangement of magnetic field sensing elements;

FIG. 9 schematically shows another embodiment of a magnetic field sensing device with a meandering-shaped and U-shaped flip conductor arrangement of a first sublayer;

FIG. 10 displays single sublayers of the flip conductor layer of FIG. 9;

FIG. 11 schematically shows a sublayer arrangement with a U-shaped flip conductor arrangement of another embodiment of a magnetic field sensing device;

FIG. 12 shows another embodiment of a magnetic field sensing device with a flip conductor and a compensation conductor arrangement;

FIG. 13 displays single sublayers of the flip conductor layer and the compensation conductor layer of FIG. 12;

FIG. 14 shows a schematic view of a three-dimensional arrangement of flip conductor layer, compensation conductor layer and Wheatstone bridge layer of another embodiment of a magnetic field sensing device.

### DETAILED DESCRIPTION OF PREFERRED EMBODIMENTS OF THE INVENTION

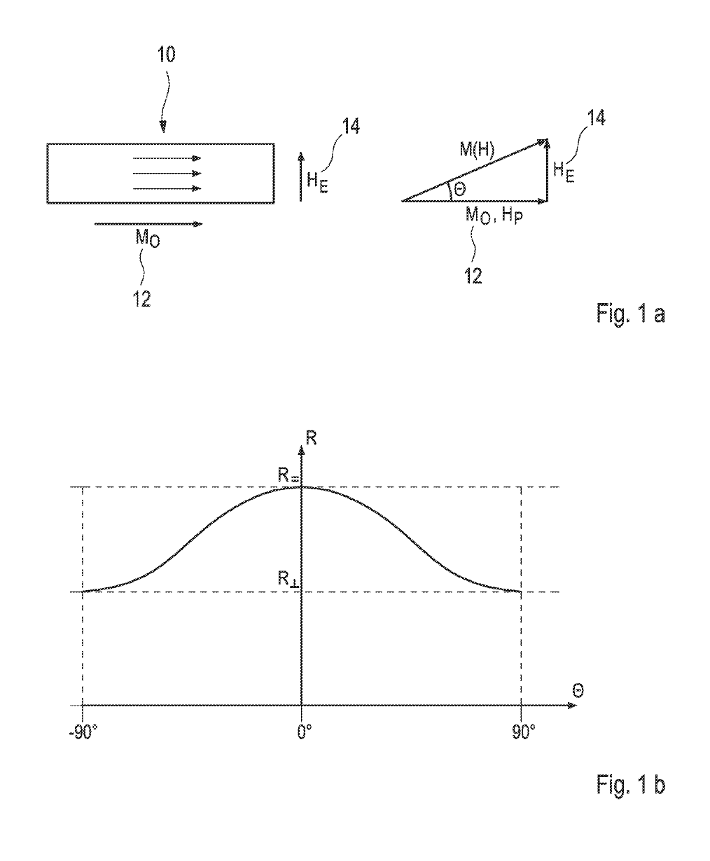

FIGS. 1a and 1b schematically show the AMR concept and resistance dependency with respect to an angle of an external magnetic field 14 of a magnetic field sensing element 10 without Barberpole structure 16. Magnetoresistance is the property of a material to change the value of its electrical resistance when an external magnetic field is applied to it. The so-called anisotropic magnetoresistance (AMR) is the property of a magnetic field sensing element 10, in which an electrical resistance depends on the angle θ between the direction of electrical current and orientation of a magnetic field M. This effect can preferably be observed in a narrow (w), thin (t) and long (l) sheet of permalloy where l>>w>>t holds. Permalloy is an alloy of 81% Ni and 19% Fe. The electrical resistance R of the element 10 has its maximum R₌ when the electrical sensing current is in parallel with the direction of a magnetic field M and has its minimum R_{⊥} when the magnetic field M is perpendicular to the current's direction. The effect is caused by a distortion of the electron-spin-alignment of the atoms due to the field M. The permalloy magnetic field sensing element 10 has an internal magnetization M₀ 12, which is typically aligned to the longitudinal direction of the AMR sensing element and to the electric current flowing through the sensing element 10. In the following it is assumed that the magnetization M is split into a component H_{P} parallel to the internal magnetization M₀ and to the sensing current, and H_{E} 14 being perpendicular to the sensing current and internal magnetization M₀ 12, whereby it is further assumed that |M₀|>>|H_{P}| holds, such that H_{P} can be neglected in the following. Considering an electrical current parallel to the magnetization M₀ 12 the following relation holds: R=R_{⊥}+(R₌−R₁₉₅)cos² (Θ) with arctan(Θ) as ratio of magnitude of external perpendicular magnetic field component H_{E} 14 and internal magnetization M₀ 12, which is depicted in FIG. 1b. The resistance sensitivity of the sensing element 10 is maximized, if |H_{E}| equals |M₀|(Θ˜45°), and is minimized, if |M₀|>>|H_{E}| and |M₀|<<|H_{E}|((Θ˜0° or 90°).

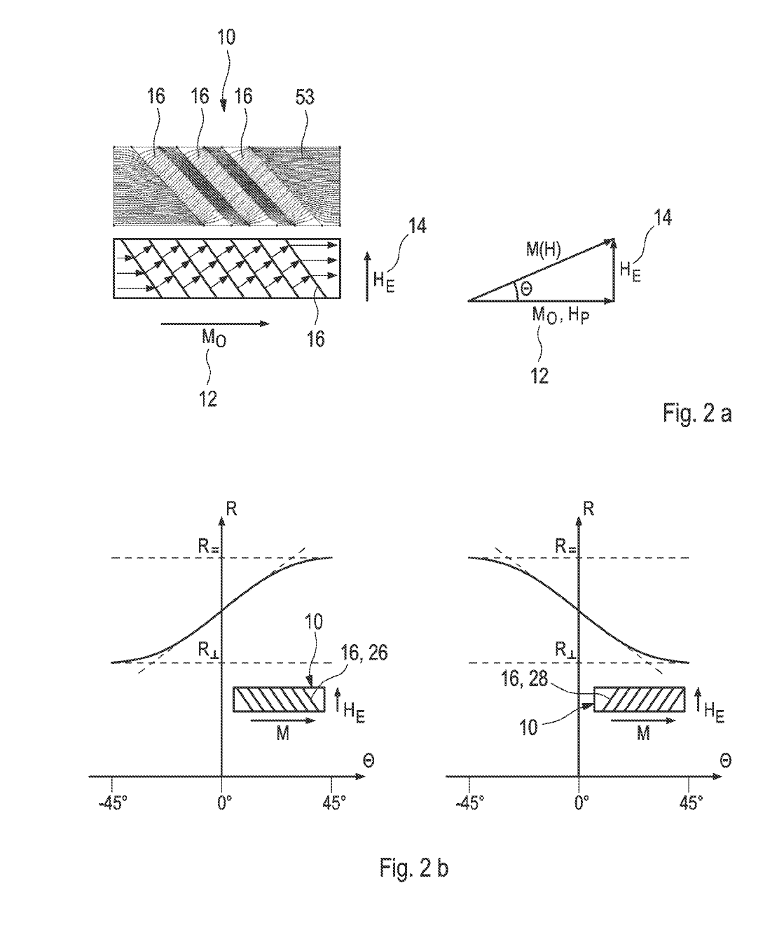

FIGS. 2a and 2b display a further developed magnetic field sensing element of FIG. 1 with a Barberpole structure 16 for enhancing the external magnetic field sensitivity, such that a maximized resistance sensitivity is reached in the case that |M₀|>>|H_{E}|((Θ˜0°. Starting from an magnetoresistive stripe element of FIG. 1, it is desirable to have a magnetic field sensor 10 with an ohmic resistance being sensitive to small magnetization variations of the sensing field H_{E} against the internal magnetization M₀. Since the R/Θ relation curve with Θ=arctan(H_{E}/M₀) is flat for small H_{E} values, typical AMR sensors are equipped with a so-called barberpole structure 16. The barberpole structure 16 comprises small highly conductive stripes made from platinum, copper, aluminum, silver or gold, which are attached to the magnetizable material (e.g. permalloy) in a 45° angle with respect to the current flow, thus forcing a 45° inclined current 53 flowing through the element 10, as shown in FIG. 2a. In this way, the R/Θ relation curve is shifted towards a linear region where small H_{E} variations lead to a linear resistance change, such that R=R_{⊥}+(R₌−R_{⊥})cos²(Θ±45°) holds. As can be seen in FIGS. 2a and 2b, the slope of the R/Θ relation curve depends on the angle of the Barberpole alignment and the direction of the internal magnetization field M₀ with respect to the sensing field H_{E}. As can be seen from above, the slope of the resistance change depends on the direction of the Barberpole angle 26, 28 and the alignment of the magnetization M₀ with respect to the sensing field H_{E} 14.

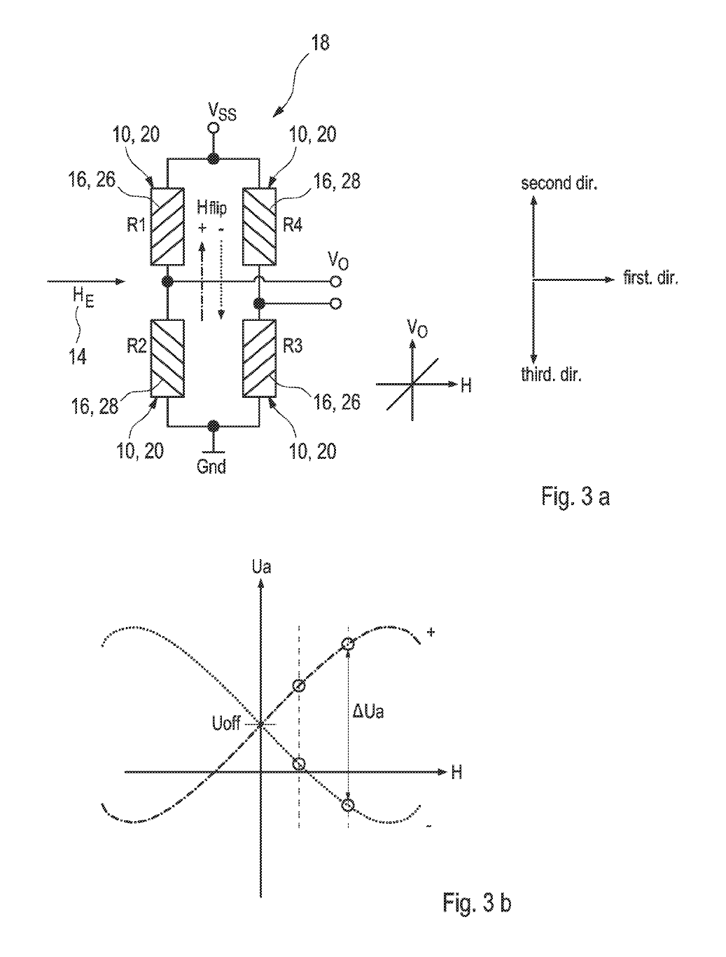

FIG. 3 shows a schematical view of a Wheatstone bridge arrangement 18 of a magnetic field sensing device for sensing a magnitude of a magnetic field component H_{E} 14. The Wheatstone bridge 18 comprises four magnetic field sensing elements 10 as bridge resistors 20 with Barberpole structures 16 having positive and negative angles 26, 28. FIG. 3b displays an Uₐ/H relation of the Wheatstone bridge 18, when a voltage Vss/Gnd is applied to the bridge 18. For sensing an external magnetic field H_{E} 14 with high sensitivity, usually four magnetic field sensing resistors 20 R1, R2, R3 and R4 comprising one or multiple sensing elements 10 are arranged in such a Wheatstone bridge circuit 18, wherein an asymmetry in the resistance values of the two legs of the Wheatstone bridge leads to a voltage difference Uₐ of the bridge. Due to temperature drift, production tolerances and other influences, a remaining offset voltage U_{off} cannot be completely made to zero, even when no sensing field H_{E} 14 is present. For sensing a vectorial magnetic field in all three dimensions, three magnetic field sensing devices have to be combined.

In order to eliminate an undesired offset voltage U_{off}, a flip concept for alternatively flipping the internal magnetization was developed which suggests to flip periodically the internal magnetization M₀ 12 of the magnetic field sensing elements 10 by a strong external magnetic flipping field H_{flip}, such that a differential value ΔUₐ of two flipped states of the Wheatstone bridge 18 can be used for determining the magnitude of the external field H_{E} 14. The internal magnetizations M₀ 12 of the single magnetic field sensing elements 10 of the bridge resistors 20 R1, R2, R3 and R4 are periodically flipped by an external magnetic flipping field H_{flip}. A typical strength of a magnetic flipping field is 0.1 to 50 mT. After each flipping step the output value ΔUₐ of the Wheatstone bridge 18 changes symmetrically around U_{off} in dependence of the two flipped magnetization states H_{flip} according to the R/Θ relation curve, as depicted in FIG. 3b. The sensor signal Uₐ is an alternating sensor signal, wherein a sensing circuit eliminates the static offset value U_{off} and determines the strength of H_{E} in dependence of ΔUₐ.

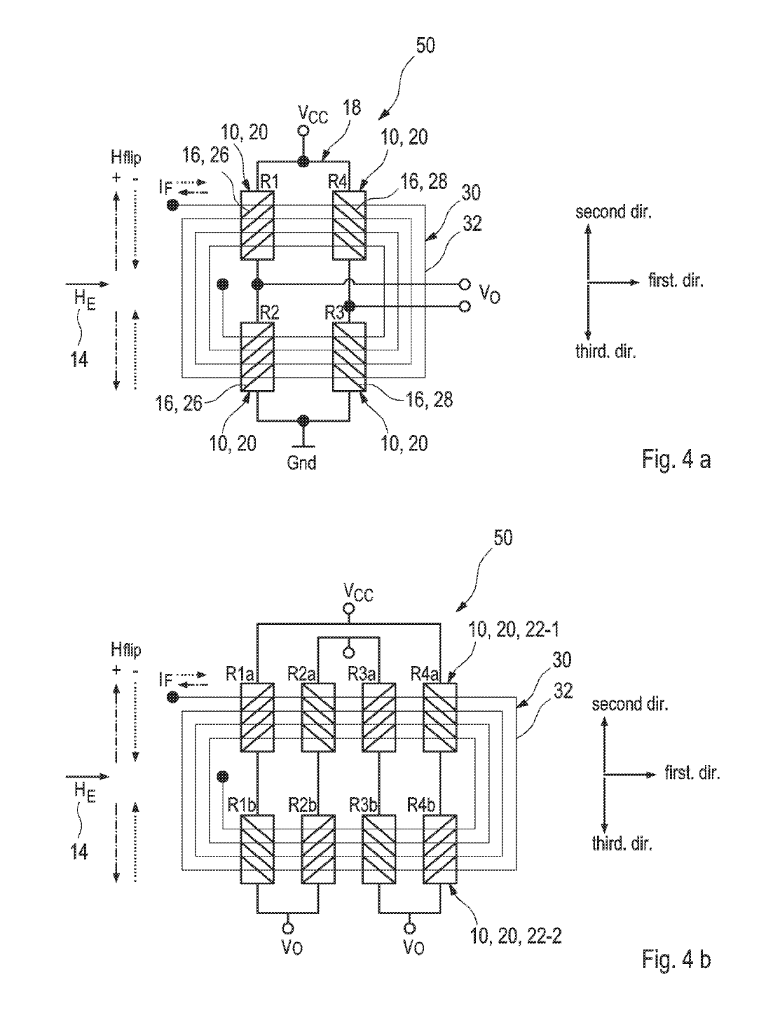

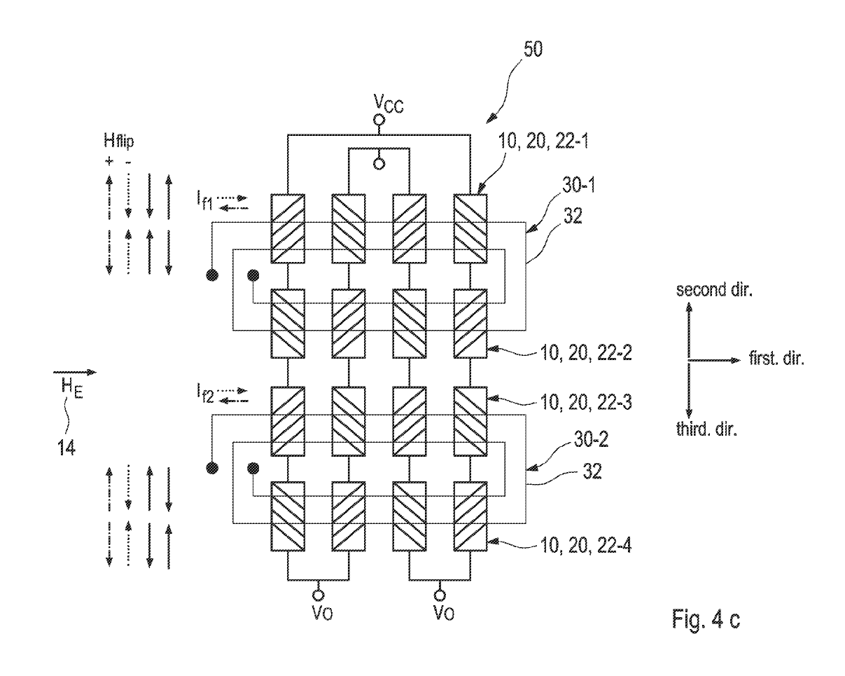

In the last years, different AMR sensor designs based on said Barberpole and flipping concept were the object of discussion. FIG. 4 shows different basic concepts of magnetic field sensing devices 50 with flip conductor 30 in an illustrative and abstract representation, wherein Wheatstone bridge resistors 20 comprise single or multiple magnetic field sensing elements 10 as subresistors 22, 22-1 to 22-4, and a single 30 or two electrically separate flip conductors 30-1, 30-2.

FIG. 4a displays a magnetic field sensing device 50 with an integrated flip coil 30, whereby each magnetic field sensing element 10 forming a resistor R1, R2, R3 and R4 20 with alternating Barberpole structures 16, 26, 28. The magnetic field sensing elements R1, R4 10 of the upper part of the Wheatstone bridge 16 are exposed to a magnetic flipping field H_{flip} of an opposing direction in contrast to the magnetic field sensing elements 10 R2, R3 of the lower part of the Wheatstone bridge 18, such that R1, R4 10 are magnetized in one direction and R2, R3 10 in the opposing direction (see dashed-dotted and dotted arrows of the H_{flip} direction). The magnetic flipping field H_{flip} is generated by a flipping current I_{F}, which can be a current pulse flowing through a flip conductor 30, comprising multiple conductor stripes 32 being formed as a spiral. Conductor stripes 32 perpendicularly oriented with respect to the magnetic field sensing elements 10 generate said magnetic flipping field H_{flip} according to Ampere's Law and conductor stripes 32 oriented in parallel to the length orientation of the magnetic field sensing elements 10 provide an electrical connection of the magnetically active conductor stripes 32. In consequence, a flipping of the R/Θ relation curve is achieved such that an offset voltage U_{off} can be eliminated and a compact sensor configuration with integrated flip coils having a small size is provided.

In 1993, the Institute for Microstructure Technology and Optoelectronics (IMO), Wetzlar, Germany proposed a sensing device 50 depicted in FIG. 4b, wherein each bridge resistor R1, R2, R3, R4 20 is split into at least two resistor subparts a and b, each one comprising a magnetic field sensing element 10 as subpart 22-1 or 22-2, having alternating Barberpole structures 16, 26, 28. Each subresistor 22-1, 22-2 (R1a, R1b . . . ) is exposed to an opposing part of the magnetic flipping field H_{flip} of the flip conductor 30 generated by a flip current I_{F} to further decrease the sensor offset caused by production tolerances or temperature variations of the sensing elements 10 and to achieve an even more compact arrangement of the resistors 20, thus leading to a smaller chip size.

FIG. 4c schematically shows a further development of the magnetic field sensing element device 50 of FIG. 4b, wherein the flip conductor 30 is split into two independent flip conductor parts 30-1 and 30-2. Each resistor 20 is divided into four subresistors 22-1 to 22-4. The two conductor parts 30-1, 30-2 individually and independently allow to adjust the magnetic flipping field H_{flip} for each subresistor 22-1, 22-2, 22-3 and 22-4. Half of the subresistors 22 of each resistor 20 cover one of the two electrically separate flip conductors 30-1, 30-2. Depending on the correlation of both flipping currents I_{F1}, I_{F2} a “normal” flipping mode (parallel currents) and a “deactivation” mode (opposing currents) can be set, thus enabling a self-calibration of the sensing device 50: The two flip conductors 30-1, 30-2 can provide four different flipping states (see +/−/0/0 H_{flip} states), whereby in case of opposing flipping currents I_{F} (H_{flip} 0/0), the sensitivity of the Wheatstone bridge is nearly eliminated (deactivated) and the output signal represents the offset voltage U_{OFF}.

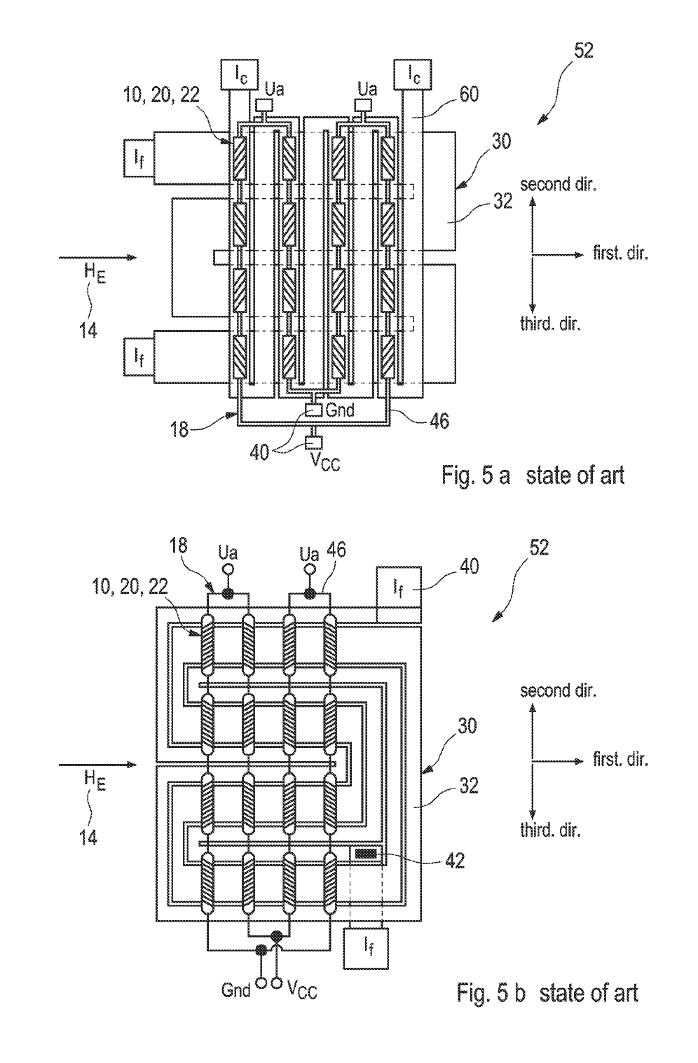

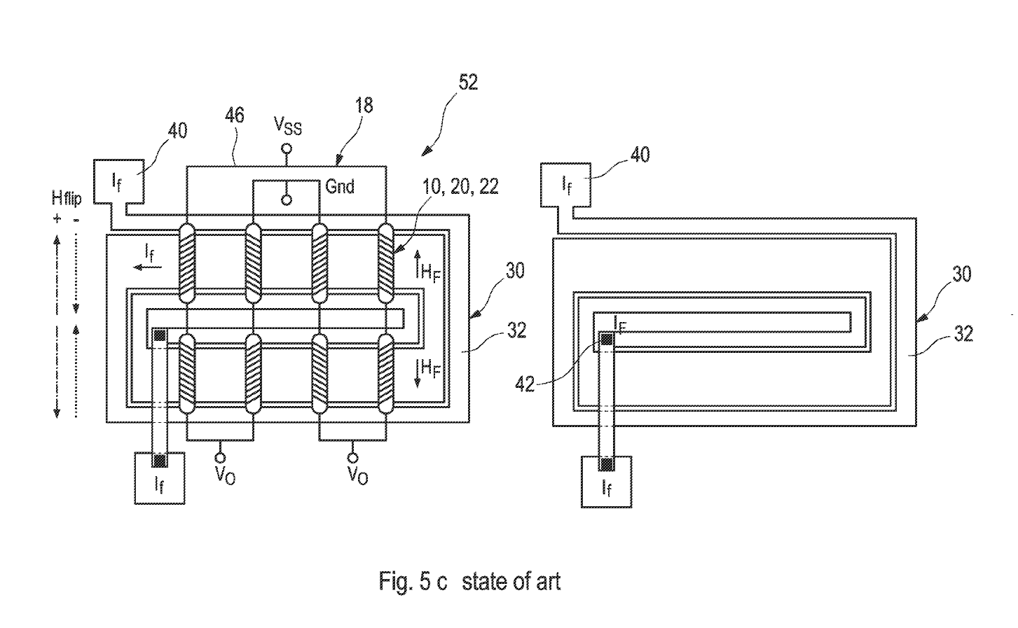

FIG. 5 shows different magnetic field sensing devices 50 as sensor chip layouts with flip conductor arrangements of a state of the art. FIG. 5a shows a first state-of-the-art magnetic field sensing device 52, which comprises a Wheatstone bridge 18, wherein each bridge resistor 20 comprises four magnetic field sensing elements 10 in the form of resistor subresistors 22. The resistors 20 are series-connected and arranged in a meandering form, whereby at each connection point between two resistors 20, contacting pads 40 (Ua, Vcc, Gnd) allow to contact the Wheatstone bride configuration 18 as explained in FIG. 3. At the lower part of the Wheatstone bride 18, supply pads 40 for ground Gnd and supply voltage V_{CC} are arranged. The upper contacting pads 40 allow access to the sensor voltage Ua of the Wheatstone bride to measure a voltage difference ΔUₐ. The Wheatstone bride 18 is arranged on top of a single flip conductor layer, wherein a meandering-shaped flip conductor 30 is arranged such that the flipping current I_{F}, which can be coupled through contacting pads 40, can flow through the contacting stripes 32 of the flip conductor 30 for generating a magnetic flipping field H_{flip} in a second or third direction. The flip conductor 30 is arranged on a single layer, determines the dimension of the overall chip structure and provides the space, in which the Wheatstone bride 18 is arranged. On an electrically insulated additional layer, a compensation conductor 60 is arranged, which is also designed in a meandering form with twice the number of meandering slopes as the number of bridge resistors 20 of the Wheatstone bridge 18, and which provide an electrical compensation field for compensating an external magnetic field. The compensation conductor 60 is based on the same principle as the flip conductor 30, but generates a magnetic field provided by a compensation current I_{c} which is not aligned longitudinally to the magnetic field sensing elements 10, but perpendicularly, thus not affecting the internal magnetization M₀ but superimposing or compensating an external magnetic field H_{E} 14 to be measured.

FIG. 5b shows a similar state-of-the-art magnetic field sensing device 52, which also comprises a Wheatstone bridge 18, wherein each bridge resistor 20 consists of four magnetic field sensing elements 10 in the form of subresistors 22. This sensing device 50 comprises a magnetic field flip conductor 30 being located on a separate single layer of the chip 50, wherein the conductor stripes 32 are arranged in a rather complicated interlaced meandering form. The electric conductors 32 of the flip conductor 30 are provided with contacting pads 40, through which a flipping current pulse I_{F} can be coupled and extracted. The lower contacting pad 40 is coupled with the conductor stripes of the flip conductor 30 by use of a via connection 42 on a different layer, which is an electric conducting through hole between two layers and a short conductor stripe for contacting the pad 40 with the first conductor stripe 32 of the flip conductor 30.

A further modification of the magnetic field sensing device 52 of FIG. 5b is depicted in FIG. 5c. The Wheatstone bridge 18 comprises four resistors 20, wherein each resistor 20 consists of two magnetic field sensing elements 10 as subresistors 22. The four bridge resistors 20 are electrically connected in series and are arranged in a meandering form over a spirally-wound magnetic flip conductor 30. Both magnetic field sensing elements 10, i.e. subresistors 22 of each resistor 20 are located on top of horizontally aligned conducting stripes 32 of a flip conductor 30. A first magnetic field sensing element 10 (subresistor 22) of each resistor 20 is arranged on top of a magnetically active conductor stripe 32 (horizontally oriented stripe 32) of the flip conductor 30 generating an upwardly directed flipping field H_{flip}, and a second element 10 is arranged on top of a magnetically active conductor stripe 32 generating a downwardly directed H_{flip} fields. The flip conductor 30 is connected to contacting pads 40 and has a spiral shape. The H_{flip} flipping field is generated by a flipping current I_{F} flowing through the flip conductor 30. The ending conductor stripe 32 at the center of the spiral is connected to the contacting pad 40 by vias 42 and a conductor stripe, which is located on an subsequent layer. On the right-hand side of FIG. 5c, the flip conductor configuration 30 as well as the connecting conductor and the vias 42 are displayed.

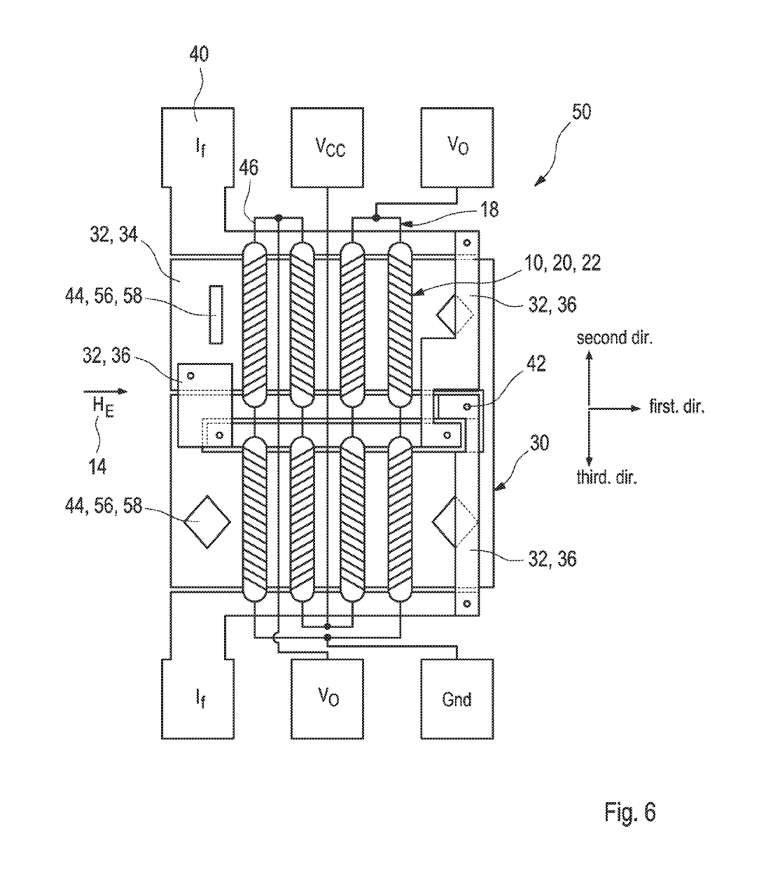

FIG. 6 shows a first embodiment of a magnetic field sensing device 50 according to the invention. The magnetic field sensor chip 50 comprises a Wheatstone bridge 18, wherein each bride resistor 20 comprises two subresistors 22, which are designed as magnetic field sensing elements 10 with alternating Barberpole structures 16, 26, 28. The Wheatstone bridge 18 is arranged on a first layer of the device 50. The Wheatstone bridge 18 is connected to four contacting pads 40 for supplying the Wheatstone bridge 18 with electric energy Vcc, Gnd and for sensing a voltage difference ΔVₒ from pads Vo as a result of an external magnetic field H_{E} 14. The Wheatstone bridge 18 is arranged on top of a flip conductor layer 38, which comprises two sublayers 38-1 and 38-2.

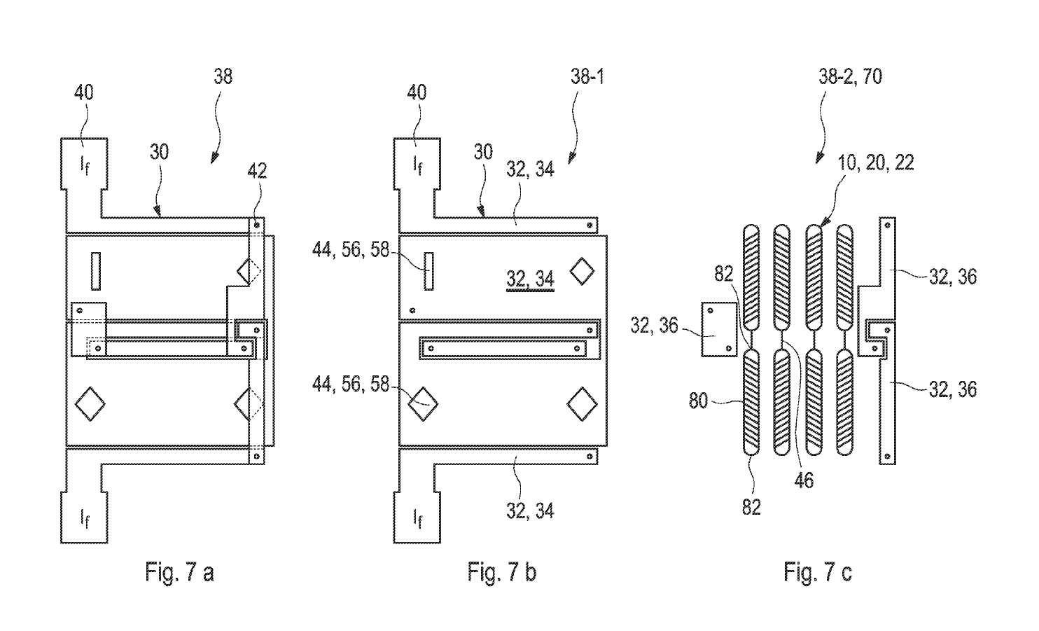

A detailed drawing of the individual sublayers is depicted in FIG. 7a to FIG. 7c. A flip conductor 30 is arranged on a flip conductor layer 30 and can be contacted by contacting pads 40, for feeding a flipping current pulse I_{F} into the conductor coil thus generating a magnetic flipping field H_{flip}. The overall design of the flip conductor 30 is double spiral-shaped, wherein the horizontally oriented conductor stripes 32, which generate a flipping field H_{flip}. in the alignment direction of the magnetic field sensing elements 10, are arranged on a first sublayer 38-1, displayed in FIG. 7b. The horizontally oriented magnetically active conductor stripes 32 of sublayer 38-1 form a first set 34 of conductor stripes for generating the flipping field H_{flip}. The conductor stripes 32 of the first set 34 are connected to vertically oriented connecting conductor stripes 32 forming a second set of conductor stripes 36 for electrical connection of the stripes 32 of the first set 34 and being arranged on a second sublayer 38-2, shown in FIG. 7c. Both sets of conductor stripes 34, 36 are electrically connected through vias 42 between the sublayers 38-1, 38-2. Thus, the flipping current I_{F} can flow through segmented conductor stripes 32 of the first and second sublayer 38-1, 38-2. The first set of conductor stripes 34 comprises conductor stripes 32 being arranged at the end parts 82 of the magnetic field sensing elements 10, which have a smaller width compared to the conductor stripes 34, which are arranged in the center part 80 of the magnetic field sensing elements 10. In this way, an increased magnetic flipping H_{flip} field can be generated at the end parts 82 of the magnetic field sensing elements 10 with respect to the center parts 80 of the sensing elements 10. Thus, the flipping current I_{F} can be lowered and the inductance of the magnetic flip conductor 30 can be decreased for achieving a solid flipping of the internal magnetization M₀ of the sensing elements 10, and due to a reduced magnetic stray field and thus lower inductance higher flip frequencies allow an increase of temporal resolution, since a higher number of measurements can be obtained during a fixed time interval. Conductor stripes 32 of the first set of conductor stripes 34 associated to the center part 80 of the magnetic field sensing elements 10 comprises current distribution elements 44 in the form of non-conducting areas 56, which are designed to distribute the flipping current I_{F} homogeneously over the conductor stripe 32. The current distribution elements 44 provide a homogeneous current distribution, such that a decreased homogeneous magnetic flipping field H_{flip} is generated in the center part 80 of the magnetic field sensing elements 10 and an increased magnetic flipping field H_{flip} is generated at the end parts 82 of the magnetic field sensing elements 10. The current distribution elements 44 help to decrease the magnitude of the magnetic flipping current I_{F} and form the current distribution profile in a way so as to optimize the flipping mechanism and to reduce electric energy consumption.

FIG. 7a schematically depicts the layout of the flip conductor 30, which is arranged on a flip conductor layer 38. The flip conductor 30 is electrically contactable via contacting pads 40, wherein the electric flipping current I_{F} can enter into and can be extracted from the flip conductor 30. The first set of conductor stripes 32, displayed in FIG. 7b, which generates the magnetic flipping field, is arranged on a first sublayer 38-1 and is connected to a second set of conductor stripes 32 arranged on a second sublayer 38-2, shown in FIG. 7c. Current distribution elements 44 in the form of rectangular and polygonal recesses 58 are arranged on the relatively wide conductor stripes being associated to the center part 80 of the magnetic field sensing elements 10. The electric connection between conductor stripes 32 of the first and second sublayer is provided by vias 40. The second sublayer 38-2 can be arranged on top of the first sublayer 38-1 and can also comprise the bridge resistors 20 of the Wheatstone bridge 18 with its subresistors 22 consisting of magnetic field sensing elements 10. Consequently, the whole sensor chip configuration 50 comprises two sublayers 38-1 as bottom layer and 38-2 as top layer, wherein the second sublayer 38-2 also comprises the Wheatstone bridge layer 70. This arrangement provides a very compact chip design with increased magnetic sensitivity and lower energy consumption.

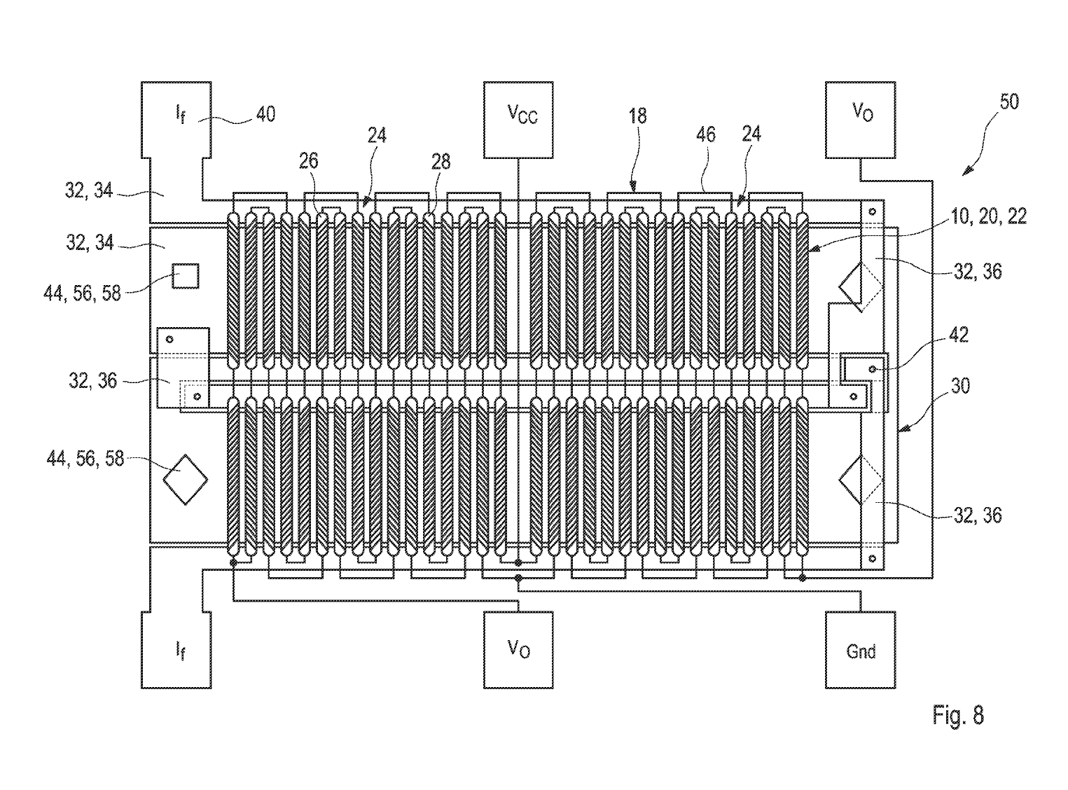

FIG. 8 displays a second embodiment of a magnetic field sensing device 50 with an interdigital arrangement 24 of bridge resistors 20. The flip conductor arrangement 30 is similar to the flip conductor of the embodiment depicted in FIGS. 6, 7. The Wheatstone bridge 18 comprises four resistors 20, whereby each resistor 20 comprises a plurality of magnetic field sensing elements 10 in the form of subresistors 22. The magnetic field sensing elements 10 of each resistor 20 are series-connected, whereby two sensing elements 10 with alternating Barberpole structures 26, 28 are arranged on magnetically active conductor stripes 32 of the first sublayer 38-1 of the flip conductor 30 generating opposing magnetic flipping fields H_{flip}. The series-connected elements 10 of each resistor 20 are arranged in a meandering form, such that interdigitating fingers are formed. The fingers of two resistors 20 interact such that the bridge resistors 20 are formed in an interdigital arrangement 24, wherein magnetic elements 10 of neighboring resistors are arranged close to another. Due to the compact arrangement of the sensing elements 10 of the bridge resistor 20 material impurities, defects or temperature variations affect both resistors in an equal manner, thus enhancing stability and accuracy of the sensing device.

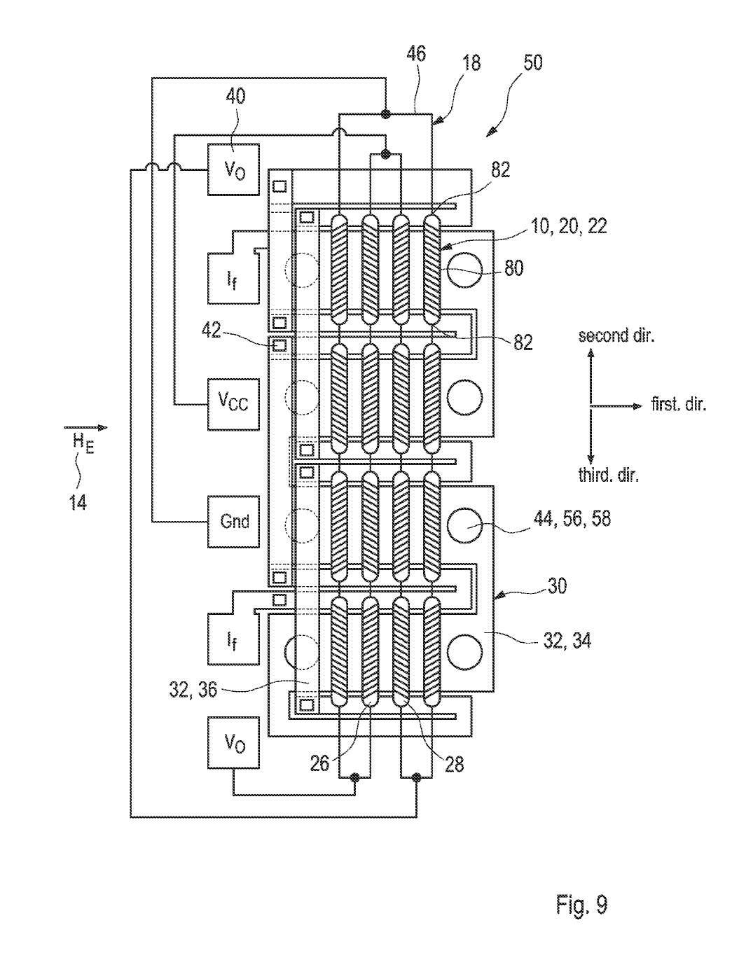

FIG. 9 shows another embodiment of a magnetic field sensing device 50, wherein the flip conductor 30 is double meandered and comprises U-shaped conductor stripes 32. In this chip arrangement 50, contacting pads 40 are arranged on a contacting side of the chip layout and individual sensing elements 10 of the bridge resistors 18 are arranged in a series connection along the double meandered flip conductor 30. Each resistor 20 comprises four magnetic field sensing elements 10 with alternating Barberpole structures 26, 28, which are located on top of a set 34 of magnetically active conductor stripes 32 of the flip conductor 30 generating opposing magnetic flipping fields.

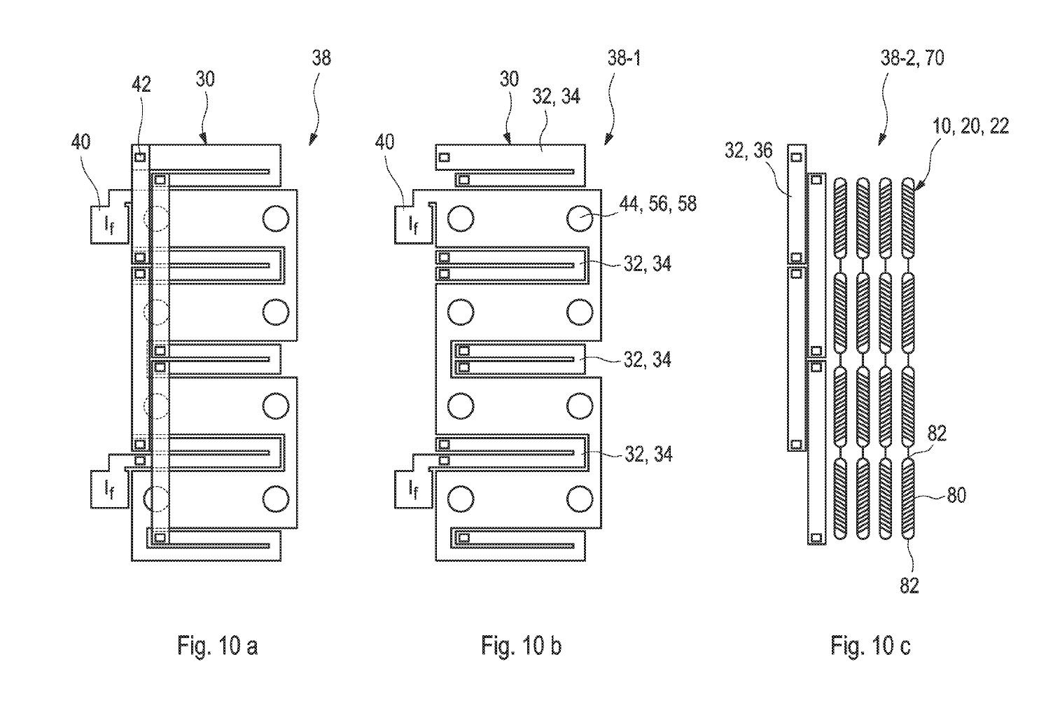

Details of the flip conductor arrangement 50 of FIG. 9 are depicted in FIG. 10. FIG. 10a reveals the structure of the flip conductor 30 located on two sublayers 38-1 shown in FIGS. 10b and 38-2, shown in FIG. 10c. Horizontally oriented first set conductor stripes 32, 34 on flip conductor layer 38-1 are arranged in a meandering form and comprise U-shaped conductor stripes associated to the end parts 82 of the magnetic field sensing elements 10. For providing a homogeneous current density of the conductor stripes 32 associated to the center part 80 of the magnetic field sensing elements 10, non-conductive recesses 58 are provided, which have a circular or elliptic shape. The current distribution elements 44 homogenize the current density of the flipping current I_{F}, thus providing a homogenous magnetic flipping field H_{flip} for the center part 80 of the magnetic field sensing elements 10. The AMR sensing elements 10 of a Wheatstone bridge layer 70 are arranged on a second sublayer 38-2 together with vertically oriented conductor stripes 36 of the second flip conductor set 32, 36. The two sets of conductor stripes 34, 36 are electrically connected by vias 42.

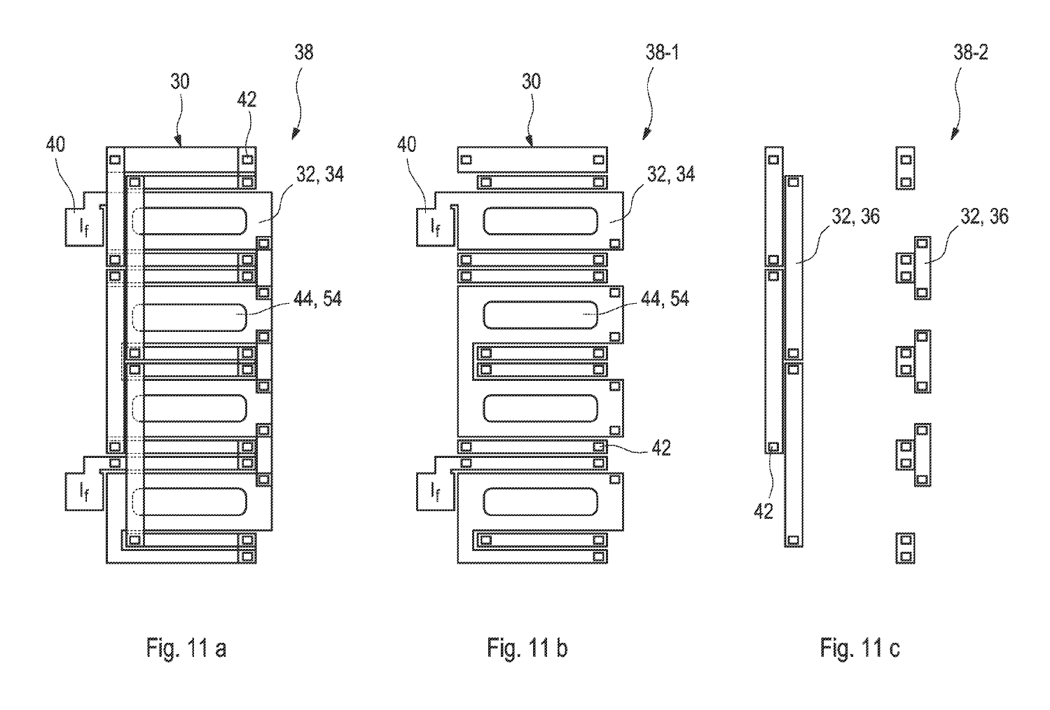

FIG. 11 depicts an alternative configuration of a flip conductor 30 of the chip configuration displayed in FIG. 9. FIG. 10a displays the overall shape of flip conductor 30 of the flip conductor layer 38. The first sublayer 38-1 of FIG. 11 b comprises only horizontally oriented magnetically active conductor stripes 32, 34, while the second sublayer 38-2 depicted in FIG. 11c only comprises vertically oriented conductor stripes 32, 36. Magnetic field sensing elements 10 (not shown) can favorably be arranged on the same layer of FIG. 11c as the second set of flip conductor stripes 36. The conductor stripes of both sublayers 38-1 and 38-2 are connected by vias. Sublayer 38-2 is arranged over sublayer 38-1 and can also comprise sensing elements 10 of a Wheatstone-bridge layer 70, not shown. The magnetically active conductor stripes 32 of the first set of conductor stripes 34 being associated to the center part 80 of the magnetic field sensing elements 10 comprise a conductance profile 54 for generating a homogenous decreased magnetic flipping field in comparison to the conductor stripes 32 associated to the end part 82 of the magnetic field sensing elements 10. In comparison to the flip conductor design of FIG. 9, the number of via connections 42 is increased, but the overall size of the chip area is further reduced due to the strict separation of vertically and horizontally oriented conductor stripes 34, 36.

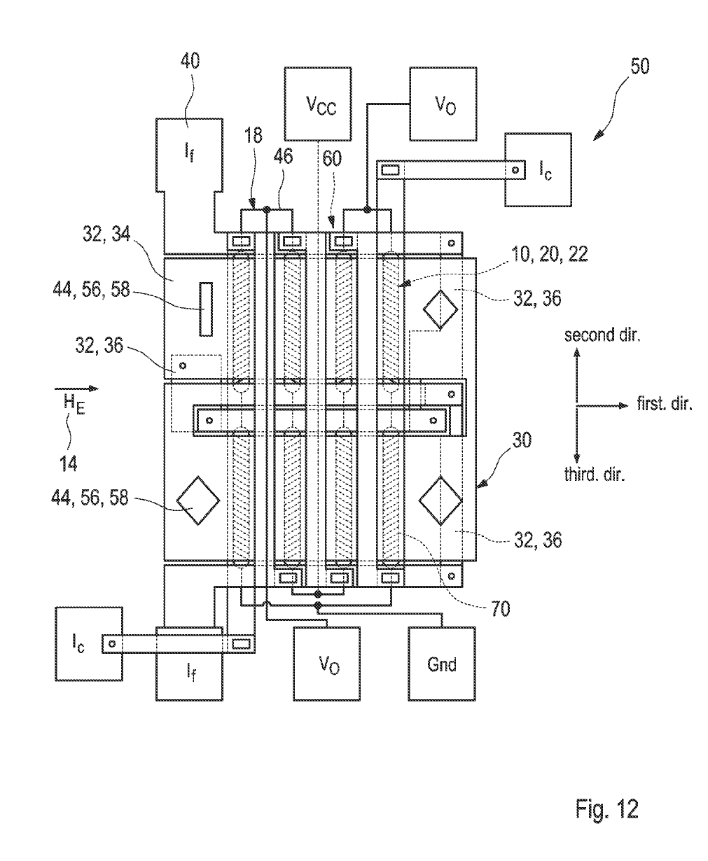

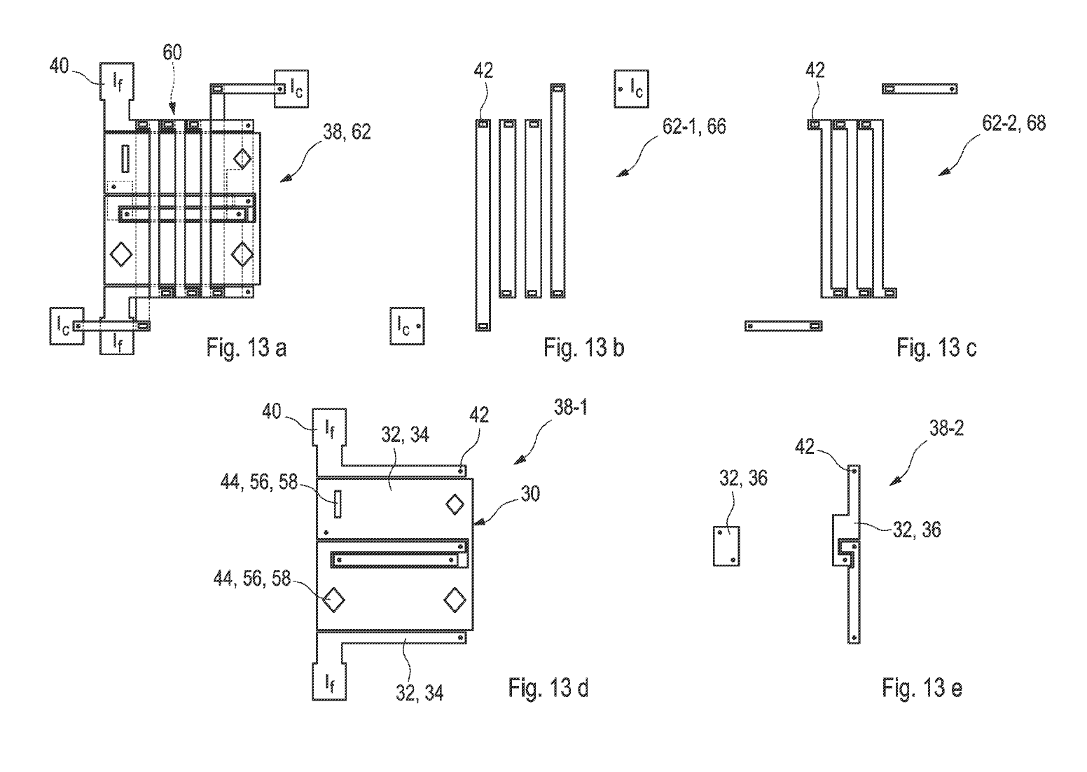

FIG. 12 displays another embodiment of a magnetic field sensing device 50 with a flip conductor 30 and a compensation conductor 60 being arranged on stacked layers 38, 611 on top of and underneath a Wheatstone bridge layer 70. The flip conductor arrangement is similar to the flip conductor of the embodiment depicted in FIG. 6. The sensing device 50 is adapted to sense a magnetic field component H_{E} in a first direction and comprises magnetic field sensing elements 10 which can be magnetized in a second or third direction depending on the direction of the magnetic flip field H_{flip}. The layer arrangement of flip conductor 30 and compensation conductor 60 of sensing device 50 is shown in FIG. 13.

FIG. 13a displays a configuration of conductor stripes 32 of the chip design of FIG. 12 comprising a flip conductor sublayer 38-1 shown in FIGS. 13d and 38-2 displayed in FIG. 13e of flip conductor 30 and sublayers 62-1 depicted in FIGS. 13b and 62-2 in FIG. 13c of a compensation conductor 60. The compensation conductor 60 as well as the flip conductor 30 comprise two sublayers 38-1, 38-2, 62-1 and 62-2 respectively, wherein the first sets of magnetically active conductor stripes 34, 66 respectively are arranged on a first sublayer 38-1, 62-1 and the second sets of conductor stripes 36, 68 respectively for electrically conducting the first set of conductor stripes 34, 66 are arranged on a second sublayer 38-2, 62-2. The sublayers 38-1, 38-2 and 62-1, 62-2 can be stacked on top of one another or can sandwich the Wheatstone bridge layer 70. Contacting pads 40 surround the layer stack assembly for conducting Wheatstone bridge 18 as well as flip conductor 30 and compensation conductor 60. The compensation conductor 60 is designed for generating an electric compensation field to compensate an external magnetic field H_{E} 14, wherein the magnetic compensation field is oriented perpendicular to the length arrangement of magnetic field sensing elements 10 (not shown). Said magnetic field sensing elements 10 (not shown) can favorably be arranged on the layer depicted in FIG. 13e in parallel to the second set of flip conductor stripes 36 of flip conductor sublayer 38-2. Since the sublayer concept of the flip conductor 30 can also be applied to the compensation conductor 60, it is also conceivable and favorable to arrange the flip conductor 30 on a single layer and to arrange the two sets of conductor stripes 66, 68 of the compensation conductor 60 on two sublayers 62-1, 62-2, thereby transferring the advantages of the invention to the compensation conductor layer arrangement 60.

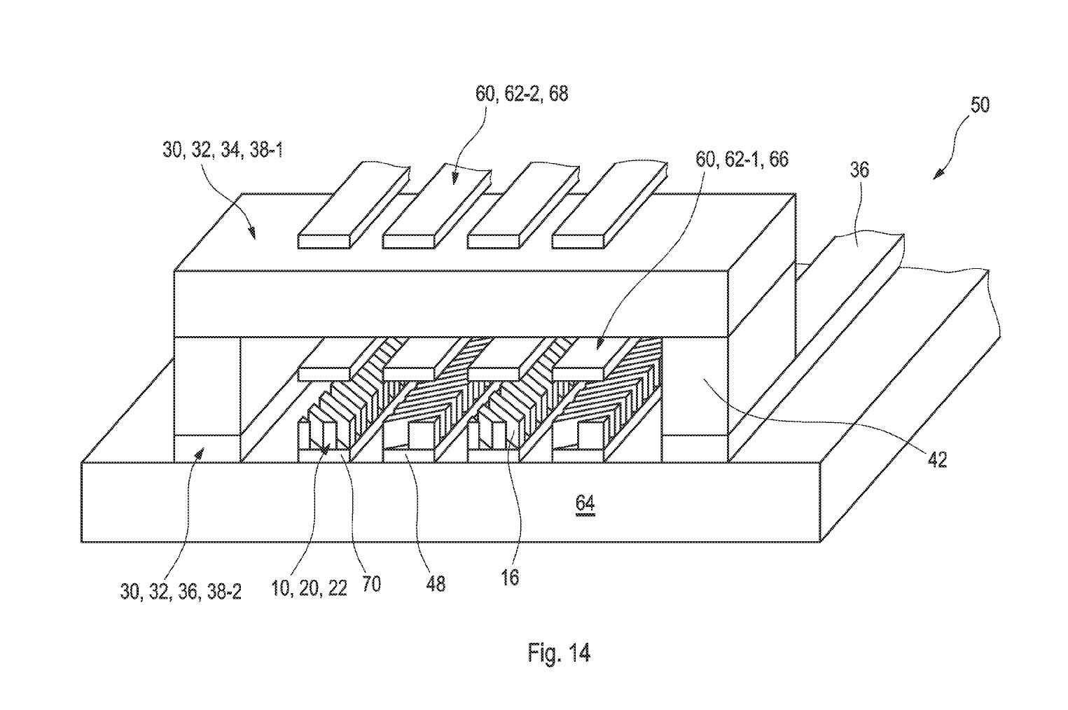

Finally, FIG. 14 displays an schematic and exploded sectional view of a three-dimensional magnetic sensor chip arrangement 50 as depicted in FIG. 12, comprising flip conductor layer 30, compensation conductor layer 60 and Wheatstone bridge layer 70 on a substrate 64, depicted in FIG. 13. The three-dimensional representation of the chip-layout is purely illustrative and does not represent any real dimension. On the substrate 64, magnetic field sensing elements 10 of four bridge resistors 20 are arranged on a Wheatstone-bridge layer 70, comprising an AMR material stripe 48, e.g. a permalloy stripe and a barberpole structure 16 made of highly conductable material, such as gold or copper. Four resistors 20 of a Wheatstone bridge 18 cover the main substrate area of the magnetic field sensing device 50. Each resistor 20 comprises a plurality of subresistors 22, whereby each subresistor 22 is a magnetic field sensing element 10. Each magnetic field sensing element 10 comprises an AMR-material stripe 48, e.g. a permalloy stripe and a barberpole structure 16 of highly conducting material on top. On the same Wheatstone-bridge layer 70 on which the magnetic field sensing elements 10 are arranged, a second flip conductor sublayer 30, 38-2 is provided comprising a second set of flip conductor stripes 32, 36 for electrically connecting conductor stripes 34 of a first set of flip conductor stripes 34—see similar configurations displayed in FIGS. 7c, 10c, 11c or FIG. 13e. The metallization of second set of flip conductor stripes 36 and of barberpole structures 16 can be identical and can be fabricated in parallel. On top of said combined layer 70, 38-2, a first compensation conductor sublayer 62-1 comprising a first set of compensation conductor stripes 66 is arranged such that a magnetic compensation field can be generated to compensate an external magnetic field H_{E}—see also configuration of FIG. 13b. On top of the first compensation conductor sublayer 62-1, a first flip conductor sublayer 38-1 is arranged comprising a set of magnetically active flip conductor stripes 34—see also FIG. 13d. The first set 34 of the flip conductor 30 is connected to the second set 36 of the magnetic flip layer 38 through via conductor elements 42, which can favorably processed in parallel to conducting stripes 32 of the first set of compensation conductor stripes 66. Finally, on top of the first flip conductor sublayer 38-1, a second compensation conductor sublayer 62-2 is arranged comprising a second set of conductor stripes 68 for connecting the first set of magnetically active conductor stripes 66 of the first compensation conductor sublayer 60-1—see FIG. 13c. The conductor stripes 32 of the first and second set of compensation conductor stripes 66, 68 are connected by vias which are not shown. A staggered design of sublayers 38-1, 38-2, 62-1, 62-2 provides a highly integrated and compact chip design with a minimal stray field and low inductance which can be operated with low power consumption at high frequency and increased sensitivity.

Due to the shape of its magnetic field sensing elements 10 and its flip conductor 30, the resistance of the flip coil 30 can be decreased down to 1Ω per sensor chip 50, such that the H_{flip} field can be generated by an 200 mA current I_{F} at a voltage V_{F} of less than 1.5 V. The special design of the flip conductor 30 generates an increased H_{flip} field at both ends 82 of the elements 10 and a smaller H_{flip} field in the center part 80 of the elements 10, such that the internal magnetization M can be flipped by an overall decreased H_{flip} field strength. Furthermore, the reduced diameter of the end parts 82 of each element 10 allows to apply a decreased H_{flip} field for solidly flipping the internal magnetization M_{O}. The improved design provides a small and compact sensor chip arrangement 50 which can be enlarged to a 3D sensor chip and which can be driven by a comparatively low voltage which can be delivered by a 1.2 V rechargeable battery of a portable device.

The present invention is not limited to the above examples, but may be varied freely within the scope of the appended claims.

### REFERENCE NUMERALS

10 Magnetic field sensing element
12 Internal magnetization M
14 External magnetic field
16 Barberpole structure
18 Wheatstone bridge
20 Bridge resistor
22 Bridge subresistor
24 Interdigital resistor subelement arrangement
26 Barperpole structure with positive angle
28 Barperpole structure with negative angle
30 Flip conductor
32 Conductor stripe
34 First set of conductor stripes for flipping field
36 Second set of conductor stripes for electrical connection
38 Flip conductor layer
40 Contacting pad
42 Via
44 Current distribution element
46 Electric connection between magnetic field sensing elements
48 AMR material stripe
50 Magnetic field sensing device
52 State-of-the-art magnetic field sensing device
53 Current density distribution
54 Conductance profile
56 Non-conducting area
58 Recess
60 Compensation conductor
62 Compensation conductor layer
64 Substrate
66 First set of compensation conductor stripes for compensation field
68 Second set of compensation conductor stripes for electrical connection
70 Wheatstone bridge layer
72
74
76
78
80 Center part of magnetic field sensing element
82 End part of magnetic field sensing element

1-15. (canceled)

16. A magnetic field sensing device comprising a plurality of functionally different layers one of which is a Wheatstone bridge layer comprising at least two resistors of a Wheatstone bridge, each resistor comprising at least one magnetic field sensing element in the form of a subresistor and a flip conductor layer which comprises at least one flip conductor for flipping the internal magnetization state of each magnetic field sensing element, said flip conductor comprising a plurality of conductor stripes arranged on at least two different flip conductor sublayers of said flip conductor layer, and vias for electrically coupling said conductor stripes with each other.

17. A magnetic field sensing device according to claim 16 comprising a first set of conductor stripes for providing a magnetic flipping field of an associated magnetic field sensing element, said conductor stripes being arranged on a first flip conductor sublayer facing a Wheatstone bridge layer side, and at least one second set of conductor stripes for providing an electrical connection of said first set of conductors stripes and arranged on at least one second flip conductor sublayer.

18. A magnetic field sensing device according to claim 17 wherein said first set of conductor stripes is oriented substantially perpendicularly with respect to a longitudinal alignment of said magnetic field sensing element and said second of
conductor stripes being oriented essentially in parallel with respect to said longitudinal alignment of said magnetic field sensing element.

19. A magnetic sensing device according to claim 17 wherein said first set of conductor stripes comprise an interdigital arrangement of perpendicularly oriented conductor stripes for providing a magnetic flipping field for a center part of said magnetic field sensing element, and at least some of the perpendicular conductor stripes providing a magnetic flipping field for end parts of said magnetic field sensing element.

20. A magnetic field sensing device according to claim 17 wherein at least one conductor stripe of said first set of conductor stripes comprises at least one current distribution element designed to provide a current distribution such that a homogenous magnetic flipping field can be excited in a center part of a magnetic sensing element.

21. A magnetic field sensing device according to claim 16 wherein said first set of conductor stripes are designed and arranged so that an increased magnetic flipping field can be provided at both end parts of each magnetic field sensing element with respect to a magnetic field provided for a center part of said magnetic field sensing element.

22. A magnetic field sensing device according to claim 16 wherein at least one of said resistors comprises at least two magnetic field sensing elements in the form of subresistors, each magnetic field sensing element comprising a Barberpole structure with a positive or a negative Barberpole alignment depending on its arrangement with respect to a current flow direction of the associated perpendicular conductor stripe of said flip conductor.

23. A magnetic field sensing device according to claim 22 comprising an interdigital arrangement of subresistors of said at least two resistors on said Wheatstone bridge layer.

24. A magnetic field sensing device according to claim 16 having a tapered form.

25. A magnetic field sensing device according to claim 16 wherein said bridge resistors are arranged on a Wheatstone bridge layer beneath said first flip conductor sublayer.

26. A magnetic field sensing device according to claim 16 wherein said bridge resistors are arranged on a Wheatstone bridge layer within said second flip conductor sublayer.

27. A magnetic field sensing device according to claim 16 comprising a compensation conductor for generating a magnetic compensation field to compensate an external magnetic field, said compensation conductor being disposed on at least one compensation conductor layer.

28. A magnetic field sensing device according to claim 27 wherein said compensation conductor comprises multiple conductor stripes arranged on at least two different compensation conductor sublayers of said compensation conductor layer and vias for electrically coupling said conductor stripes with each other such that a first set of compensation conductor stripes for providing a magnetic compensation field is arranged on said first compensation conductor sublayer and a second set of compensation conductor stripes for providing an electrical connection of said first set of compensation conductor stripes is arranged on said second compensation conductor sublayer, said first set of compensation conductor stripes being arranged above and adjacent to said Wheatstone bridge layer and beneath said first flip conductors sublayer.

29. A magnetic field sensing device according to claim 27 wherein at least a part of said compensation conductor is essentially U-shaped.

30. A magnetic field sensing device according to claim 27 wherein at least a part of said compensation conductor is essentially spiral-shaped.

31. A magnetic field sensing device according to claim 27 wherein at least a part of said compensation conductor is arranged in an essentially meandering form.

32. A magnetic field sensing device according to claim 16 wherein at least a part of said flip conductor is essentially U-shaped.

33. A magnetic field sensing device according to claim 16 wherein at least a part of said flip conductor is essentially spiral-shaped.

34. A magnetic field sensing device according to claim 16 wherein at least a part of said flip conductor is arranged in an essentially meandering form.

35. A magnetic field sensing device according to claim 16 comprising at least two electrically separated flip conductors for independently flipping a magnetization state of at least one magnetic field sensing element of said at least one of said bridge resistors.
